(19) United States
(12) Patent Application Publication
(10) Pub. No.: US 2017/0138673 A1
(43) Pub. Date: May 18, 2017

(54) Planar Heat Pipe

(71) Applicant: Furukawa Electric Co., Ltd., Tokyo (JP)

(72) Inventors: Hirofumi Aoki, Tokyo (JP); Hiroshi Sakai, Tokyo (JP); Tatsuro Miura, Tokyo (JP); Yoshikatsu Inagaki, Tokyo (JP)

(21) Appl. No.: 15/418,811

(22) Filed: Jan. 30, 2017

Related U.S. Application Data
(63) Continuation of application No. PCT/JP2015/070677, filed on Jul. 21, 2015.

(30) Foreign Application Priority Data
Aug. 1, 2014 (JP) 2014-157713

(51) Int. Cl. F28D 15/02; H05K 7/20; H01L 23/427; F28D 15/04; F28F 19/00

(52) U.S. Cl. CPC F28D 15/0233; F28D 15/04; F28F 19/00; H01L 23/427; H05K 7/20336; F28F 2275/067

(57) ABSTRACT

A planar heat pipe including a container having a protruded portion provided at a central part thereof, the protruded portion having a hollow portion formed by two plate-shaped bodies opposing each other, and a working fluid enclosed in the hollow portion. The hollow portion is provided with a wick structure. A peripheral portion surrounding the protruded portion is sealed by welding by applying heat. A groove is provided around the protruded portion between the protruded portion and a welded portion welded by the welding by applying heat.

### CROSS REFERENCE TO RELATED APPLICATIONS

This is a continuation application of International Patent Application No. PCT/JP2015/070677, filed Jul. 21, 2015, which claims the benefit of Japanese Patent Application No. 2014-157713, filed Aug. 1, 2014, the full contents of all of which are hereby incorporated by reference in their entirety.

### BACKGROUND

Technical Field

The present disclosure relates to a planar heat pipe in which a distortion of a hollow portion is suppressed and a warp of a container as a whole is reduced.

Background

Electronic components such as semiconductor devices installed in electric/electronic devices produce an increased amount of heat due to high density packaging or the like along with improvement in functionality, and importance of cooling of such electronic components is recently increasing. Planar heat pipes may be used for cooling electronic components.

Accordingly, a planar heat pipe has been proposed wherein a hollow portion having a wick structure is sealed by seam welding (Japanese Laid-Open Patent Publication No. 2003-314979). However, with seam welding, a width of a welded portion of a planar heat pipe tends to become greater, and there is also a drawback that it is not suitable for high-speed welding.

Further, a planar heat pipe wherein a hollow portion having a wick structure is sealed by ultrasonic welding has been proposed (Japanese Laid-Open Patent Publication No. 2003-80378). However, with ultrasonic welding, a welding strength is limited and thus it is difficult to further improve airtightness of the hollow portion as compared to the conventional art.

Further, a planar heat pipe wherein a hollow portion having a wick structure is sealed by pressure welding has been proposed (Japanese Laid-Open Patent Publication No. 2002-310581). However, since pressure welding is a joining technique by plastic deformation, a joining strength is limited. Therefore, it is difficult to achieve a higher airtightness of a hollow portion having a wick structure than that of the conventional art, and distortion may be produced in a heat pipe.

Accordingly, recently, a planar heat pipe is being proposed wherein a hollow portion having a wick structure is sealed by welding using a YAG laser, since a hollow portion having an improved airtightness can be obtained and it is also suitable for high-speed welding. However, with welding by a YAG laser, a difference between a width of a laser welded portion on a laser beam irradiation side surface of the container and a width of the laser welded portion on a surface opposite the laser beam irradiation side of the container becomes greater. That is, with the welding using the YAG laser, the width of the welded portion on the laser beam irradiation side surface of the container becomes much broader than the width of the laser welded portion on the opposite surface. Thus, there is a drawback that, when the welded portion solidifies, a warp is produced in a planar heat pipe as a whole due to the difference in width of the welded portions on both of the surfaces mentioned above and a drawback that heat of fusion of the container material produced during the welding transfers up to the hollow portion and a distortion is produced in the hollow portion.

The present disclosure is related to providing a planar heat pipe in which a distortion of a hollow portion having a wick structure and a warp of the planar heat pipe as a whole are reduced.

### SUMMARY

According to an aspect of the present disclosure, a planar heat pipe includes a container having a protruded portion provided at a central part thereof, the protruded portion having a hollow portion formed by two plate-shaped bodies opposing each other, and a working fluid enclosed in the hollow portion. The hollow portion is provided with a wick structure. A peripheral portion surrounding the protruded portion is sealed by welding by applying heat, and a groove is provided around the protruded portion between the protruded portion and a welded portion welded by the welding by applying heat. According to the planar heat pipe of the present disclosure, the groove has a depth that is greater than or equal to a tenth but less than or equal to one-third of a total thickness of the two plate-shaped bodies. According to the planar heat pipe of the present disclosure, the groove has a width that is greater than or equal to a welded width of the welded portion on a surface of the container at a side where heat is applied, but less than a shortest distance from an end portion on a protruded portion side of the welded portion to an end portion of the protruded portion on the surface at a side on which heat is applied. According to the planar heat pipe of the present disclosure, a welded width of the welded portion on a surface of the container at a side where heat is applied is greater than or equal to 1/10 of a total thickness of the two plate-shaped bodies and less than or equal to a shortest distance from an end portion on a protruded portion side of the welded portion to an end portion of the protruded portion on the surface at a side on which heat is applied. Note that the aforementioned laser welding technique in which welding is performed by applying heat is not particularly limited, and may be techniques such as laser welding, resistance welding, Tig welding, and electron beam welding. Laser welding is preferable since it provides a narrow welding region and improvement in a degree of freedom of machining shape and machining tact time.

With the planar heat pipe of the present disclosure, a welded width of the welded portion on a surface of the container at a side where heat is applied is greater than or equal to 10 μm but less than or equal to 300 μm.

With the planar heat pipe of the present disclosure, a ratio of a welded width of the welded portion on a surface of the container at a side where heat is applied to a welded width of the welded portion on a surface opposite to the surface of the container where heat is applied is 1:1 to 1:0.80.

With the planar heat pipe of the present disclosure, the protruded portion has a thickness of greater than or equal to a half of a total thickness of the two plate-shaped bodies.

With the planar heat pipe of the present disclosure, a material of the container is one of copper, copper alloy, aluminum, aluminum alloy, nickel, nickel alloy and stainless steel.

With the planar heat pipe of the present disclosure, a total thickness of the two plate-shaped bodies is greater than or equal to 0.05 mm but less than or equal to 1.0 mm.

With the planar heat pipe of the present disclosure, the welding by applying heat is laser beam welding.

According to an aspect of the present disclosure, a planar heat pipe includes a container having a protruded portion provided at a central part thereof, the protruded portion having a hollow portion formed by two plate-shaped bodies opposing each other, and a working fluid enclosed in the hollow portion, the hollow portion being provided with a wick structure, a peripheral portion surrounding the protruded portion being sealed by laser welding, a shortest distance from an end portion on a protruded portion side of the laser welded portion to an end portion of the protruded portion on a surface of the container at a side on which laser beam irradiation is applied is greater than or equal to a total thickness of the two plate-shaped bodies, the laser welded width of the welded portion on the surface of the container at the side where laser beam irradiation is applied is greater than or equal to 1/10 of the total thickness of the two plate-shaped bodies and less than or equal to the shortest distance from the end portion of the protruded portion side of the laser welded portion to the end portion of the protruded portion on the surface at the side on which laser beam irradiation is applied.

According to an aspect of the present disclosure, since a groove is provided around the protruded portion, the transfer of heat of fusion of a container material produced during welding and reaching the hollow portion is suppressed by the groove, and thus a distortion of the hollow portion is reduced. Also, with the groove being provided around the protruded portion, and a welded width of the welded portion on the surface at a side where heat is applied being greater than or equal to MO of a total thickness of the two plate-shaped bodies and less than or equal to a shortest distance from an end portion on a protruded portion side of the welded portion to an end portion of the protruded portion on the surface at a side on which heat is applied, the transfer of heat of fusion of a container material produced during welding and reaching the hollow portion is suppressed, and thus, a distortion of the hollow portion is reduced. Further, since a difference between the welded width of the welded portion in the surface at a side where heat is applied and the welded width of the welded portion in the opposite surface is small, a warp of the planar heat pipe as a whole is reduced when solidifying the welded portion. That is to say, the planar heat pipe having a groove of the present disclosure is a planar heat pipe in which a distortion of the hollow portion is reduced and a warp as a whole is reduced while having an improved joining strength of the welded portion.

According to an aspect of the present disclosure, since the welded width of the welded portion on a surface of the container at a side where heat is applied is greater than or equal to 10 μm but less than or equal to 300 μm, the difference between the welded width of the welded portion in the surface at a side where heat is applied and the welded width of the welded portion in the opposite surface is positively made smaller.

According to an aspect of the present disclosure, since a ratio of a welded width of the welded portion on a surface of the container at a side where heat is applied to a welded width of the welded portion on a surface opposite to the surface of the container where heat is applied is 1:1 to 1:0.80, a warp in the planar heat pipe as a whole is positively reduced.

According to an aspect of the present disclosure, a shortest distance from an end portion on a protruded portion side of the laser welded portion to an end portion of the protruded portion on a surface of the container at a side on which laser beam irradiation is applied is greater than or equal to a total thickness of the two plate-shaped bodies, the laser welded width of the welded portion on the surface of the container at the side where laser beam irradiation is applied is greater than or equal to 1/10 of the total thickness of the two plate-shaped bodies and less than or equal to the shortest distance from the end portion of the protruded portion side of the laser welded portion to the end portion of the protruded portion on the surface at the side on which laser beam irradiation is applied, it is possible to prevent heat of fusion of the container produced during the welding from being transferred to the hollow portion and causing a distortion of the hollow portion. Further, since a difference between the welded width of the laser welded portion on the surface of the container at a side where laser beam irradiation is applied and the welded width of the laser welded portion on the opposite surface is small, a warp of the planar heat pipe as a whole is reduced when solidifying the welded portion. That is to say, the planar heat pipe having a groove of the present disclosure is a planar heat pipe in which a distortion of the hollow portion is reduced and a warp as a whole is reduced while having an improved joining strength of the laser welded portion.

### BRIEF DESCRIPTION OF DRAWINGS

FIG. 1 is a sectional view showing a part of a planar beat pipe according to a first embodiment of the present disclosure.

FIG. 2 is a sectional view showing a part of a planar heat pipe according to a second embodiment of the present disclosure.

### DETAILED DESCRIPTION

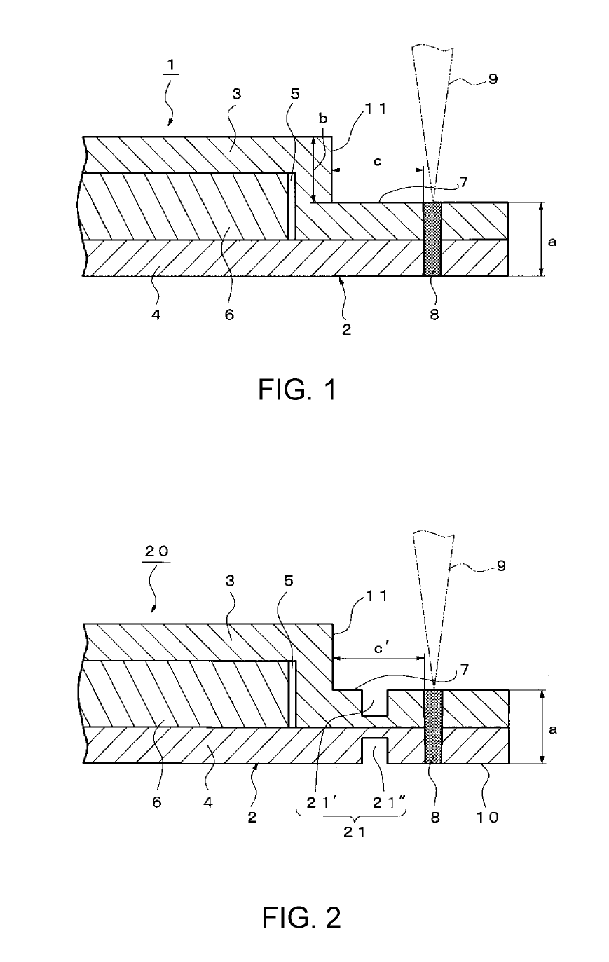

Hereinafter, a planar heat pipe according to a first embodiment of the present disclosure will be described below with reference to the drawings. As shown in FIG. 1, a planar heat pipe 1 according to the first embodiment includes a container 2, which has a rectangular shape in a plan view, and a working fluid (not shown). The container 2 includes two plate-shaped bodies opposing each other, namely one plate-shaped body 4 and another plate-shaped body 3, that are placed on top of each other, thus providing a protruded portion 11 having a hollow portion 5 formed at a central part of the container 2. The working fluid is enclosed in the hollow portion 5. A wick structure 6 having a capillary tube structure is accommodated in the hollow portion 5.

The one plate-shaped body 4 has a flat plate shape. The other plate-shaped body 3 also has a flat plate shape and a central part thereof is plastically deformed into a protruded shape. This part of the other plate-shaped body 3 protruding outwardly and plastically deformed into a protruded shape constitutes the protruded portion 11 of the container 2. In FIG. 1, the protruded portion 11 protrudes perpendicularly to a surface of a peripheral portion surrounding the protruded portion 11. An inside portion of the protruded portion 11 constitutes the hollow portion 5. As to the planar heat pipe 1, the peripheral portion surrounding the protruded portion 11 is laser welded to thereby seal the hollow portion 5 and give airtightness to the hollow portion 5.

The planar heat pipe 1 has a laser welded portion 8 that is formed by welding, by a laser beam 9, a rim portion 7 of the other plate-shaped body 3 having the central part machined into a protruded shape, in other words, a rim portion of the container 2 where the protruded portion 11 is not formed. The one plate-shaped body 4 and the other plate-shaped body 3 are joined by the laser welded portion 8. The laser welded portion 8 is provided at a position where a shortest distance between an end part of the laser welded portion 8 on a protruded portion 11-side and an end part of the protruded portion 11 on a surface subjected to laser beam irradiation, in other words, a boundary between the surface of the peripheral portion surrounding the protruded portion 11 and the protruded portion 11 (distance c in FIG. 1. Hereinafter, also referred to as “distance c”) has a size that is greater than or equal to a total thickness of the one plate-shaped body 4 and the other plate-shaped body 3 that are placed on top of each other (thickness a in FIG. 1. Hereinafter, also referred to as “thickness a”). Thereby, since heat of fusion of the container material produced during welding can be prevented from reaching the hollow portion 5, a distortion of the hollow portion 5 of the planar heat pipe 1 is reduced.

The lower limit value of distance c is a size corresponding to thickness a, and preferably 1.5 times the size corresponding to thickness a to positively prevent heat of fusion from reaching the hollow portion 5, and particularly preferably 2.0 times the size corresponding to thickness a to positively avoid an influence of a distortion due to a residual stress produced by the welding with the laser beam 9. On the other hand, the upper limit value of distance c is not particularly limited, but in order to downsize the planar heat pipe 1 to make it possible to install the planar heat pipe 1 in a small space, it is preferably 5.0 times the size corresponding to thickness a, and, further preferably 4.0 times, and particularly preferably 3.0 times the size corresponding thickness a to positively reduce a residual stress and to speed-up the machining by decreasing a distance welded by the laser beam 9.

Note that a boundary between the laser welded portion 8 and a portion that has not been laser welded can be determined by observing a surface of the laser welded portion 8 or observing a cross section of the laser weld surfaces 8 with the naked eye. Herein, a “welded width” means a width of a softened deformed region having a linear shape that is produced by welding with heat and which is an average value obtained when the welding region was measured evenly at ten points by a microscope.

The lower limit value of the welded width of the laser welded portion 8 on the laser beam irradiation-side surface (in FIG. 1, a surface on a side of the other plate-shaped body 3 having a central part that is machined into a protruded shape) is, considering a bonding strength of the laser welded portion 8, 1/10 of the size corresponding to thickness a, and, preferably ⅕ of the size corresponding to thickness a, considering a gas barrier property, and particularly preferably a quarter of the size corresponding to thickness a. On the other hand, the upper limit value of the welded width of the laser welded portion 8 on a laser beam irradiation-side surface is a size corresponding to the shortest distance between the end part of the laser welded portion 8 on the protruded portion 11-side and the end part of the protruded portion 11 (i.e., distance c), to obtain a planar heat pipe 1 having a reduced total warp, by decreasing a difference between the welded width of the laser welded portion 8 on the laser beam irradiation-side surface of the container 2 (in FIG. 1, a surface on a side of the other plate-shaped body 3) and the surface opposite to the welded width of the laser welded portion 8 (in FIG. 1, a surface on a side of the one plate-shaped body 4), and preferably, ⅗ of the size corresponding to distance c to suppress any slight warp in the vicinity of the laser welded portion 8, further preferably a half of the size corresponding to distance c to positively reduce a residual stress, and particularly preferably a quarter of the size corresponding to distance c to downsize the planar heat pipe 1. Accordingly, a size corresponding to thickness a and a size corresponding to distance c is determined such that a position and a welded width of the laser welded portion 8 are within the aforementioned ranges.

The welded width of the laser welded portion 8 on the laser beam irradiation side surface of the container 2 is not particularly limited as long as it is within the aforementioned range, and as a specific example, in the case of the container 2 having a thickness a of 100 μm, the lower limit value is 10 preferably 20 μm, and particularly preferably 25 μm. On the other hand, the upper limit value is, for example, 500 μm, preferably 300 μm, more preferably 250 μm, and particularly preferably 125 μm.

A ratio of a welded width of the laser welded portion 8 on the laser beam irradiation side surface of the container 2 to a welded width of the laser welded portion 8 in a surface on the side opposite to the laser beam irradiation side surface of the container 2 is preferably 1:1 to 1:0.80 to obtain a planar heat pipe 1 having a reduced total warp, further preferably 1:1 to 1:0.85 to suppress any slight warp in the vicinity of the laser welded portion 8, and particularly preferably 1:1 to 1:0.90 to positively suppress a difference in residual stresses between the laser beam irradiation side surface of the container 2 and the surface on the side opposite.

A laser that is capable of welding with a welded width of the laser welded portion 8 may be a laser with a small condensing diameter on the laser beam irradiation side surface of the container 2, and, for example, the condensing diameter is 20 to 200 μm. Such a laser may include a fiber laser.

The thickness of the protruded portion 11 (thickness b in FIG. 1) can be selected as appropriate, and, for example, considering a balance between flexibility and a cooling efficiency of the planar heat pipe 1, it is preferably greater than or equal to a half of the size corresponding to thickness a but less than or equal to the size corresponding thickness a. Also, thickness a can be selected as appropriate, and, for example, preferably greater than or equal to 0.05 mm but less than or equal to 1.0 mm for downsizing, and particularly preferably greater than or equal to 0.1 mm but less than or equal to 0.8 mm considering pressure resistance and workability.

The material of the container 2 may be, for example, copper, copper alloy, aluminum, aluminum alloy, or stainless steel. The working fluid enclosed in the hollow portion 5 of the container 2 can be selected as appropriate depending on the suitability with the material of the container 2, and may be, for example, water, chlorofluorocarbon alternative, fluorinert, or cyclopentane.

The wick structure 6 having a capillary tube structure may, for example, a thin plate having a mesh, a wire or the like.

The planar heat pipe according to the second embodiment of the present disclosure will described with reference to the drawings. Note that components that are the same as those of the planar heat pipe 1 according to the first embodiment will be described with the same reference numerals.

As shown in FIG. 2, a planar heat pipe 20 according to the second embodiment has a recessed groove 21 formed therein in a region between the protruded portion 11 and the laser welded portion 8 welded by the laser beam 9. In FIG. 2, a single recessed groove 21′ is formed in the rim portion 7, namely a peripheral portion surrounding the protruded portion 11, on a laser beam irradiation side surface of the other plate-shaped body 3 having a central part machined into a protruded shape. Further, with respect to a recessed groove 21′, one recessed groove 21″ is formed at a rim portion 10 of the one plate-shaped body 4 corresponding to a position in a direction parallel to a thickness direction of the container 2. The recessed groove 21′ is formed to surround the periphery of the protruded portion 11 formed at the central part of the container 2, and the recessed groove 21″ is formed to surround the periphery of the central part corresponding to the position of the protruded portion 11. Also, the recessed groove 21′ and the recessed groove 21″ have the same cross-sectional shape and the same width and depth, and are formed such that a bottom face portion of the recessed groove 21′ and a bottom face portion of the recessed groove 21″ are opposed.

Since the recessed grooves 21′ and 21″ suppress the transfer of heat of fusion of the container material which was produced during the laser beam welding to the hollow portion 5, a distortion of hollow portion 5 is further reduced.

The width recessed grooves 21′ and 21″ has a size corresponding to greater than or equal to the welded width of the laser welded portion 8 on the laser beam irradiation side surface of the container 2, but less than a shortest distance between an end part of the laser welded portion 8 on a protruded portion 11-side and an end part of the protruded portion 11 (hereinafter, also referred to as “distance c′”), and the depth of the recessed grooves 21′ and 21″ has a size corresponding to greater than or equal to 1/10 but less than or equal to one-third, and preferably greater than or equal to ⅙ but less than or equal to one-third of a total thickness of the one plate-shaped body 4 and the other plate-shaped body 3 placed on top of each other (thickness a in FIG. 2. Hereinafter, also referred to as “thickness a”). Therefore, distance c′ of the planar heat pipe 20 has a size that is greater than the welded width of the laser welded portion 8 on the laser beam irradiation side surface.

The width of the recessed grooves 21′ and 21″ is not particularly limited as long as it is within the range mentioned above, but to positively suppress the transferring of the heat of fusion to the hollow portion 5, the lower limit value of the width is preferably 1.5 times the welded width of the laser welded portion 8 on the laser beam irradiation side surface, and particularly preferably 2.0 times the welded width of the laser welded portion 8 on the laser beam irradiation side surface. On the other hand, the upper limit value of the width of the recessed grooves 21′ and 21″ is, to prevent a temperature increase in a region from the end part of the laser welded portion 8 on the protruded portion 11-side to the end part of the protruded portion 11, preferably ⅘ of the size corresponding to distance c′, and particularly preferably two-thirds of the size corresponding to distance c′.

The depth of the recessed grooves 21′ and 21″ is not particularly limited as long as it is within the aforementioned range, but to positively suppress the transferring of the heat of fusion to the hollow portion 5, and to ensure the mechanical strength of the peripheral portion surrounding the protruded portion 11, it is particularly preferably greater than or equal to ⅕ but less than or equal to a quarter of the size corresponding to thickness a.

The welded width of the laser welded portion 8 of the planar heat pipe 20 is similar to that of the planar heat pipe 1 according to the first embodiment mentioned above. Specifically, the lower limit value of the welded width of the laser welded portion 8 on the laser beam irradiation side surface (in FIG. 2, a surface on a side of the other plate-shaped body 3 having a central part that is machined into a protruded shape) is, considering a bonding strength of the laser welded portion 8, for example, 1/10 of the size corresponding to thickness a, and preferably ⅕ of the size corresponding to thickness a concerning a gas barrier property, and particularly preferably a quarter of the size corresponding to thickness a. On the other hand, the upper limit value of the welded width of the laser welded portion 8 on the laser beam irradiation side surface is a size corresponding to distance c′, to obtain a planar heat pipe 1 having a reduced total warp by decreasing a difference between the welded width of the laser welded portion 8 on the surface of the container 2 on which laser beam irradiation is applied (in FIG. 2, a surface on a side of the other plate-shaped body 3 side) and the surface opposite to the welded width of the laser welded portion 8 (in FIG. 2, a surface on a side of the one plate-shaped body 4 side), and preferably, ⅗ of the size corresponding to distance c to suppress any slight warp in the vicinity of the laser welded portion 8, further preferably a half of the size corresponding to distance c′ to positively reduce a residual stress, and particularly preferably a quarter of the size corresponding to distance c′ to downsize the planar heat pipe 1.

With the planar heat pipe 20, since the recessed grooves 21′ and 21″ suppress the transferring of heat of fusion produced by laser beam welding to reach the hollow portion 5 as mentioned above, the distance c′ can be made shorter than the distance c of the planar heat pipe 1.

The distance c′ is not particularly limited, but its lower limit value is preferably a half of the size corresponding to thickness a to prevent a distortion of the hollow portion 5 while downsizing the planar heat pipe 20, further preferably a size corresponding to thickness a to positively prevent the distortion of the hollow portion 5, and particularly preferably 1.5 times of the size corresponding to thickness a to avoid an influence of a distortion by a residual stress produced by the welding with the laser beam 9. On the other hand, the upper limit value f distance c′ is not particularly limited, but in order to downsize the planar heat pipe 20 to make it possible to install the planar heat pipe 20 in a small space, it is preferably 5.0 times the size corresponding to thickness a, and, further preferably 4.0 times, and particularly preferably 3.0 times the size corresponding thickness a to positively reduce a residual stress and to speed-up the machining by decreasing a distance welded by the laser beam 9.

With the planar heat pipe 20 according to the second embodiment, a position and the welded width of the laser welded portion 8 are determined such that the recessed grooves 21′ and 21″ are in a range of the aforementioned size.

An exemplary use of the planar heat pipe according to the embodiment of the present disclosure will now be described. Herein, a case in which a flexible printed wiring board on which CPU, etc. are mounted inside an electronic device such as a PC is cooled using the planar heat pipe of the present disclosure will be described by way of example. Depending on the condition of a gap inside an electronic device and the accommodation condition of the flexible printed wiring board, the planar heat pipe is bent as appropriate to thermally connect the flexible printed wiring board to the heat input side of the planar heat pipe. At the heat output side of the planar heat pipe, fins for heat dissipation are provided as needed. Thereby, a flexible printed wiring board accommodated in a small space inside an electronic device can be cooled in a planar manner.

Other embodiments of the present disclosure will be described below. With the planar heat pipe 1, 20 according to each of the embodiments, a wick structure 6 having a capillary structure was accommodated in the hollow portion 5, but, alternatively, a wick structure may be formed on an inner wall of hollow 5.

With the planar heat pipe 1, 20 according to each of the embodiments, a surface of the other plate-shaped body 3 having a central part machined into a protruded shape is irradiated with the laser beam 9, but alternatively, a surface of the one plate-shaped body 4, the central part of which is not machined into a protruded portion, may be irradiated with the laser beam 9. In a case where the surface of the one plate-shaped body 4 side is irradiated with the laser beam 9, when setting the position of the laser welded portion 8, an end portion of the protruded portion 11 becomes a portion on a surface of the one plate-shaped body 4 where the boundary portion between the surface of the peripheral portion surrounding the protruded portion 11 of the other plate-shaped body 3 and the protruded portion 11 is moved in a direction parallel to the thickness direction of the container 2. That is to say, the end portion of the protruded portion 11 in the one plate-shaped body 4 becomes a portion on a surface of the one plate-shaped body 4 corresponding to the position of the boundary between the surface of the peripheral portion surrounding the protruded portion 11 of the other plate-shaped body 3 and the protruded portion 11.

With the planar heat pipe 20 according to the second embodiment; the recessed groove 21′ and the recessed groove 21″ have the same cross-section and the same width and depth, but alternatively, they may have different cross-section and/or different width and depth.

### EXAMPLES

Examples of the present disclosure will be described below, but the present disclosure is not limited to these examples unless it goes beyond the scope of the present disclosure.

### Example 1

Two pieces of plate-shaped bodies (thickness 0.1 mm) having a single recessed groove having a width of 0.3 mm and a depth of 0.05 mm at a position corresponding to a part surrounding a periphery of a protruded portion (height 0.2 mm) having a hollow portion were placed on top of each other with back surfaces of the plate-shaped bodies being in contact with each other. Then, a planar heat pipe of Example 1 was manufactured by laser welding (width of laser beam 0.02 mm) the peripheral portion surrounding the recessed groove. Note that the recessed groove of the plate-shaped body in which the protruded portion is formed and on the laser beam irradiation side and the recessed groove of the plate-shaped body in which the protruded portion is not formed and not the laser beam irradiation side are formed at the same position interfacing at contact surfaces of opposing plate-shaped bodies. Also, since the plate-shaped body has a thickness of 0.1 mm, the protruded portion (hollow portion) and a portion other than the recessed groove of the planar heat pipe has a thickness of 0.2 mm.

### Comparative Example 1

A planar heat pipe of Comparative Example 1 was manufactured in a manner similar to that Example 1 except that plate-shaped bodies having a thickness of 0.1 mm and having no recessed groove were placed on top of each other.

Evaluation of Flatness

For each of the planar heat pipe of Example 1 and the planar heat pipe of Comparative Example 1, a height of the protruded portion (hollow portion) was measured using a laser displacement meter (high-speed high precision CCD laser displacement meter keyence LK-G30, three-dimensional arm: IAI TABLE TOP TT). Points of measurement were 21 points in total, such that seven points are arranged at an equal interval in a longitudinal direction from one end portion to the other end portion and three points equally are arranged at an equal interval in a lateral direction from one end portion to the other end portion. Using coordinates of these 21 points of measurement, an imaginary plane, which is taken as a reference, was calculated by a least square method, and a flatness of the protruded portion (hollow portion) was calculated by “maximum height from the imaginary plane among the 21 points of measurement—minimum height from the imaginary plane among the 21 points of measurement”.

Calculation results of the flatness is as indicated below.

### Example 1: Flatness 0.3 mm

### Comparative Example 1: Flatness 0.5 mm

From the above, Example 1 having a recessed groove in a peripheral portion surrounding the protruded portion (hollow portion) has a better flatness of the protruded portion (hollow portion) as compared to Comparative Example 1 without a recessed groove, and it was possible to prevent the distortion of the protruded portion (hollow portion).

The planar heat pipe of the present disclosure has a reduced distortion in the hollow portion having a wick structure and a reduced warp in the planar heat pipe as a whole, as thus it is particularly useful in a field of uniformly cooling in a planer manner a heating element that is an object to be cooled.

What is claimed is:

1. A planar heat pipe comprising:
a container having a protruded portion provided at a central part thereof, the protruded portion having a hollow portion formed by two plate-shaped bodies opposing each other; and
a working fluid enclosed in the hollow portion,
the hollow portion being provided with a wick structure,
a peripheral portion surrounding the protruded portion being sealed by welding by applying heat,
a groove being provided around the protruded portion between the protruded portion and a welded portion welded by the welding by applying heat.

2. The planar heat pipe according to claim 1, wherein the groove has a depth that is greater than or equal to a tenth but less than or equal to one-third of a total thickness of the two plate-shaped bodies.

3. The planar heat pipe according to claim 1, wherein the groove has a width that is greater than or equal to a welded width of the welded portion on a surface of the container at a side where heat is applied, but less than a shortest distance from an end portion on a protruded portion side of the welded portion to an end portion of the protruded portion on the surface at a side on which heat is applied.

4. The planar heat pipe according to claim 1, wherein a welded width of the welded portion on a surface of the container at a side where heat is applied is greater than or equal to 1/10 of a total thickness of the two plate-shaped bodies and less than or equal to a shortest distance from an end portion on a protruded portion side of the welded portion to an end portion of the protruded portion on the surface at a side on which heat is applied.

5. The planar heat pipe according to claim 1, wherein a welded width of the welded portion on a surface of the container at a side where heat is applied is greater than or equal to 10 μm but less than or equal to 300 μm.

6. The planar heat pipe according to claim 1, wherein a ratio of a welded width of the welded portion on a surface of the container at a side where heat is applied to a welded width of the welded portion on a surface opposite to the surface of the container where heat is applied is 1:1 to 1:0.80.

7. The planar heat pipe according to claim 1, wherein the protruded portion has a thickness of greater than or equal to a half of a total thickness of the two plate-shaped bodies.

8. The planar heat pipe according to claim 1, wherein a material of the container is one of copper, copper alloy, aluminum, aluminum alloy, nickel, nickel alloy and stainless steel.

9. The planar heat pipe according to claim 1, wherein a total thickness of the two plate-shaped bodies is greater than or equal to 0.05 mm but less than or equal to 1.0 mm.

10. The planar heat pipe according to claim 1, wherein the welding by applying heat is laser beam welding.
